(19) United States
(12) Patent Application Publication
(10) Pub. No.: US 2007/0274042 A1
(43) Pub. Date: Nov. 29, 2007

(54) MODULAR POWER FOR CHEST AND CABINETS

(75) Inventors: Daniel L. JACKSON, Center Point, IA (US); Steven Frederick KOHAGEN, Waverly, IA (US); John P. MALLEY, Cedar Falls, IA (US); Jim HAND, Glen Ellyn, IL (US); Greg HOLDERFIELD, Oak Park, IL (US); Eric HYMAN, South Grafton, MA (US); David CHESLEY, Duxbury, MA (US)

Correspondence Address: CALFEE, HALTER & GRISWOLD LLP, 1400 KEYBANK CENTER, 800 SUPERIOR AVENUE, CLEVELAND, OH, 44114, US

(73) Assignee: WATERLOO INDUSTRIES, INC., Waterloo, IA (US)

(21) Appl. No.: 11/753,984

(22) Filed: May 25, 2007

Related U.S. Application Data
(60) Provisional application No. 60/808,707, filed on May 26, 2006.
(60) Provisional application No. 60/811,183, filed on Jun. 6, 2006.
(60) Provisional application No. 60/874,547, filed on Dec. 13, 2006.
(60) Provisional application No. 60/916,601, filed on May 8, 2007.

(51) Int. Cl. H05K 7/20

(52) U.S. Cl. 361/695

(57) ABSTRACT

A power module that fits to the top of a storage chest or cabinet is connected to electrical power and routes the electrical power to drawers and/or cavities within the chest or cabinet. The electrical power is continuously available while the power module is connected to electrical power so that the drawers or cavities have a continuous source of power whether or not the drawers or cabinet doors are open or closed. The chest or cabinet may include receptacles having a standard configuration that connects to a variety of devices including, for example, lights, heaters, and battery chargers. The chest or cabinet may include electrically powered features, such as, for example, lights, clocks, audio/visual equipment, computers, tool chargers, air compressors, refrigerators, wireless communications devices, and heaters. The chest or cabinet may also include one or more exterior lights.

### CROSS REFERENCE TO RELATED APPLICATIONS

This non-provisional application claims the benefit of U.S. Provisional Patent Application Nos. 60/808,707, entitled “Tool Chest with Light” and filed on May 26, 2006, 60/811,183, entitled “Powered Toolbox” and filed on Jun. 6, 2006, 60/874,547, entitled “Storage Container” and filed on Dec. 13, 2006, and 60/916,601 entitled “Modular Power for Chests and Drawers” and filed on May 8, 2007. The entire disclosure of the listed provisional applications is incorporated herein by reference for all purposes, to the extent that it is not conflicting with the present application.

### TECHNICAL FIELD

The invention pertains to the field of storage chests and cabinets.

### BACKGROUND

Certain drawer chests include limited connections to an electrical power source for a dedicated purpose. For example, U.S. Patent Publication No. 2002/0171335 to Held describes a chest of drawers in which at least one of the drawers includes a built-in current storage means, such as a battery. When the drawer is closed, the current storage means is connected to a power source and the storage means is charged. When the drawer is open, the current storage means can be used to power an electrical accessory until the stored energy is depleted. U.S. Pat. No. 5,276,310 to Schmidt et al. concerns a toolbox with drawers that include electric heaters to heat tools held within the drawer. The heater is connected to a power source in the back of the toolbox when the drawer is closed. tools held within the drawer. The heater is connected to a power source in the back of the toolbox when the drawer is closed.

### SUMMARY

A power module that fits to the top of a storage chest or cabinet is connected to electrical power and routes the electrical power to drawers and/or cavities within the chest or cabinet. One or more power receiving devices is present in the power module such as, for example, a wiring harness, audio visual equipment, a message center, an ultrasonic cleaner, a wireless communication device, a battery charger, a refrigerator, or an air compressor. The electrical power is continuously available while the power module is connected to electrical power so that the drawers or cavities have a continuous source of power whether or not the drawers or cabinet doors are open or closed. The chest or cabinet may include receptacles having a standard configuration that connects to a variety of devices including, for example, lights, heaters, and battery chargers. The chest or cabinet may include electrically powered features such as, for example, lights, clocks, audio equipment, computers, and heaters. The chest or cabinet may have one or more drawers or pull-out work surfaces with underside lighting.

Further features and advantages of the invention will become apparent from the following detailed description made with reference to the accompanying drawings.

### BRIEF DESCRIPTION OF THE DRAWINGS

In the accompanying drawings, which are incorporated in and constitute a part of this specification, embodiments of the invention are illustrated, which, together with the description of the invention serve to illustrate the principles of this invention. The drawings and detailed description are not intended to and do not limit the scope of the invention or any subsequent claims in any way. Instead, the drawings and description only describe embodiments of the invention and other embodiments of the invention not described are encompassed by this disclosure of the invention.

FIG. 1 is a perspective view of a chest that includes a power top module constructed in accordance with an embodiment of the present invention;

FIG. 2 is a front perspective view of the power top module of FIG. 1;

FIG. 3 is a top perspective view of the power top module of FIG. 1;

FIG. 4 is a bottom view of the power top module of FIG. 1;

FIG. 5 is a rear perspective view of the power top module of FIG. 1;

FIG. 6 is an exploded fragmentary view of the power top module of FIG. 1;

FIG. 7 is a rear view of the chest of FIG. 1 with the rear wall removed to reveal a wiring harness that can be used in conjunction with power top module of FIG. 1;

FIGS. 8-9 are bottom views of a drawer in the chest of FIG. 1 that receives power from the power top module of FIG. 1;

FIG. 10 is an exploded bottom view of the drawer of FIGS. 8 and 9;

FIG. 11 is a bottom view of the chest of FIG. 1 that includes an under chest light;

FIG. 12 is a perspective view of a storage unit that includes a power module constructed in accordance with an another embodiment of the present invention;

FIGS. 13A and 13B are fragmentary views of pull-out members of the storage unit of FIG. 12;

FIG. 14 is a schematic circuit diagram that can be used to provide electrical features to a storage unit constructed in accordance with an embodiment of the present invention; and

FIGS. 15A and 15B are perspective views of a tool storage unit constructed in accordance with an embodiment of the present invention.

### DESCRIPTION OF THE INVENTION

The Detailed Description of the Invention merely describes preferred embodiments of the invention and is not intended to limit the scope of the specification or any issued claims in any way. Indeed, the invention as described is broader than and unlimited by the preferred embodiments, and the terms in the specification have their full ordinary meaning.

Many storage chests and cabinets could provide increased utility by featuring convenient access to electrical power as part of the chest or cabinet. For example, a light source located within a drawer or cabinet may illuminate the contents or surroundings when the drawer or door is opened. Heating or cooling mechanisms within the drawer or cabinet may maintain the interior temperature within an acceptable range for the contents so that the chest or cabinet can be installed in a location exposed to extreme temperatures. A source of power within the drawer or cabinet can be used to energize battery chargers so that tools or other battery operated devices stored in the drawer or cabinet can be charged during storage.

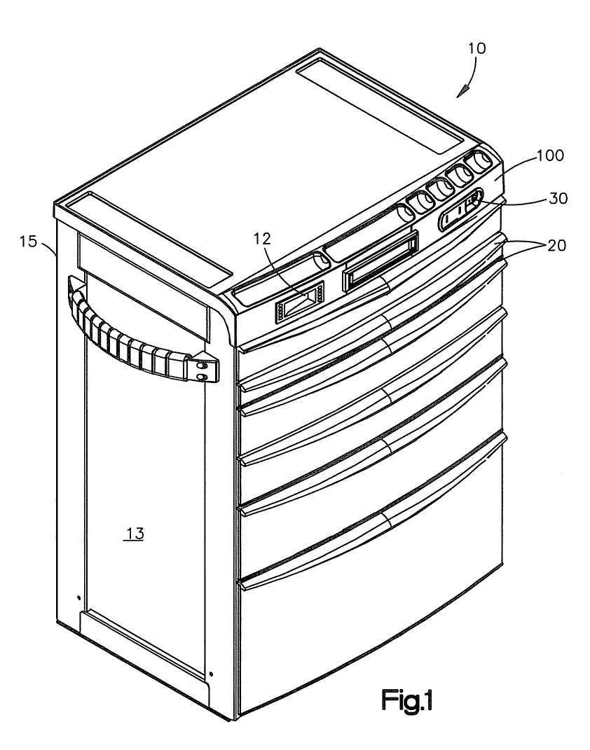

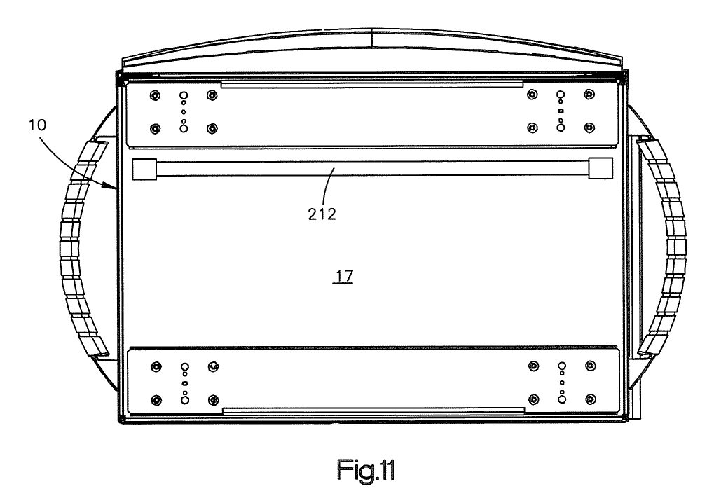

FIG. 1 shows a storage chest 10 that is adapted for use in storing tools. A chest is shown for exemplary purposes only. It should be apparent to one skilled in the art that the invention may be practiced on tool chests, tool cabinets, or combination tool chest and cabinet units. The chest 10 is formed by a structural weldment that includes rear wall 15, side walls 13, and bottom 17 (FIG. 11). The weldment defines a cavity in which a number of drawers 20 are installed. The chest also includes a power top module 100 that can be connected to a source of electrical power, such as a household outlet (not shown). Prior to entering the power top module 100, the AC power from a household outlet may be rectified into DC power with a standard AC to DC converter that is commonly used to power many devices. Other features of the power top module 100 include an LCD unit 12 that provides a user interface to a clock and radio that are part of the LCD unit and receive power from the power top module.

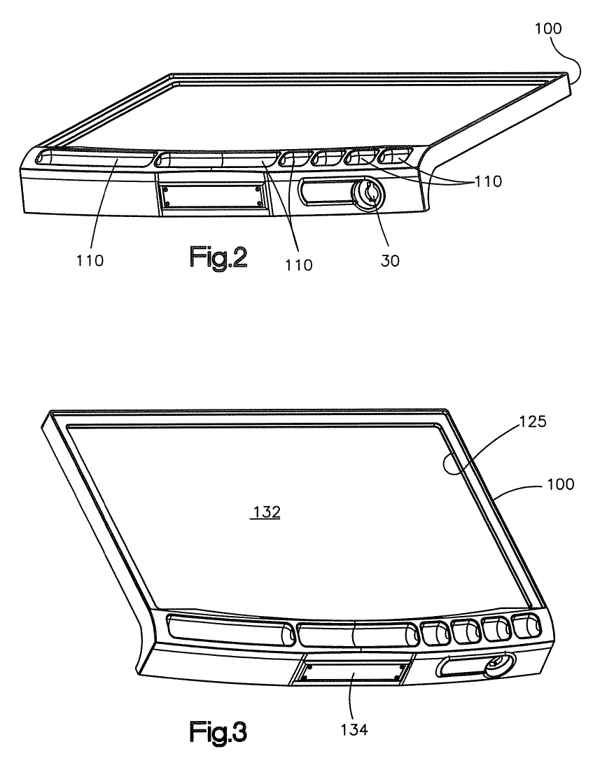

FIGS. 2 and 3 show the power top module 100 removed from the chest 10. In addition to providing a means for receiving power, the power top module includes other features such as a work surface 132 that is surrounded by a short wall 125 that projects vertically from surface around its periphery. The wall 125 helps prevent objects from rolling off the surface and contains liquid spills. A plurality of holding cups 110 of various sizes are molded into the power top module to contain small objects such as screws and small hand tools. A key cylinder 30 is present in the power top module 100 to allow a user to secure the drawers in the closed position. A lighted nameplate 134 holder is molded into the front surface of the power top module 100.

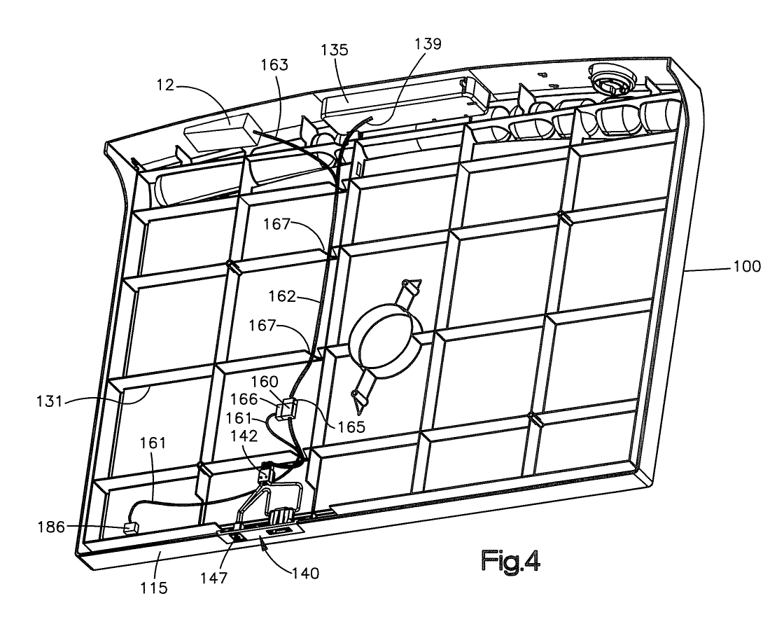

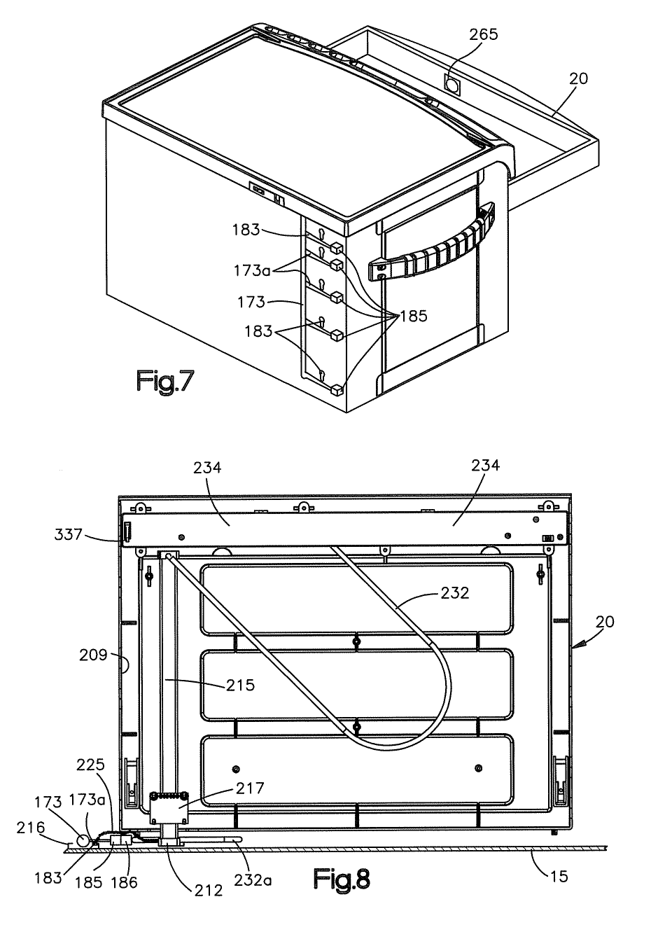

FIG. 4 is a bottom view of the power top module 100 that shows some aspects of the power management components that allow the top to be used to receive power from an external source and route the power to various locations within the chest. The power top module 100 is molded from plastic and includes a number of strengthening ribs arranged in a grid. A power module receptacle unit 140 is snapped into the back of the power top module 100. Power from the power module receptacle unit is routed to a T connector 160 that is connected to a face connector 166. The face connector provides power on a nameplate lead 162 to a light 135 that is positioned behind the nameplate holder 134 (FIG. 3) to back-light a nameplate (not shown) that is installed in the nameplate holder. Several strengthening ribs include a notch 167 though which the various leads are routed. A harness connector 166 is connected to the T connector 160 and provides power on a harness lead 161 to a chest wiring harness 173 (FIG. 7). As will be described in more detail below, the chest wiring harness 173 runs down the rear of the chest and includes leads that are configured to mate with the connector 186 and that can be used to power various features within the chest.

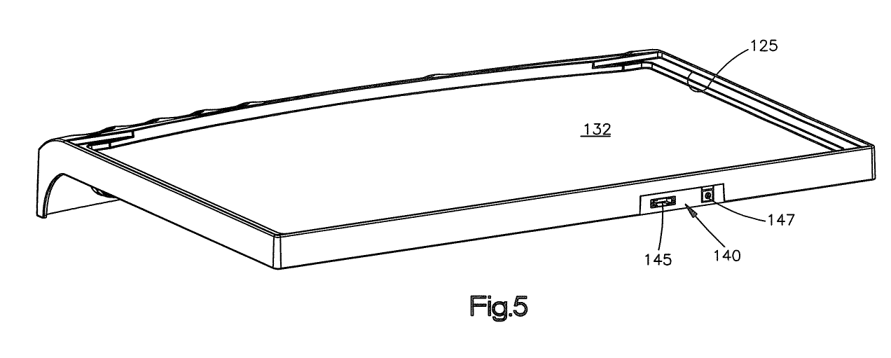

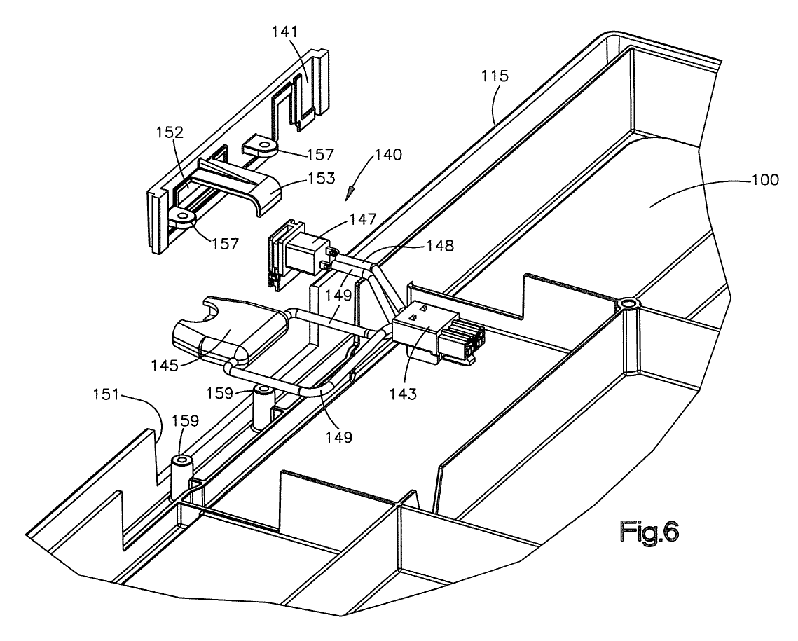

FIGS. 5-6 illustrate the power module receptacle unit 140 in more detail. FIG. 5 shows the installation of the power module receptacle unit in the rear of the power top module 100. FIG. 6 is an exploded view of the power module receptacle unit 140. A receptacle plate 141 is sized to fit within a corresponding notch 151 in the rear of the power top module. The receptacle plate may be molded from plastic and includes an integrally molded fuse holder tang 153 and two mounting ears 157 with openings to accept mounting screws. A Molex type connector 147 is pressed into the receptacle plate. The connector 147 is configured to accept a standard plug from a AC to DC converter as discussed above. First and second power leads 148, 149 are connected to the connector 147. The first power lead 148 is routed directly to a receptacle connector 143. A fuse holder 145 is also pressed into the receptacle plate. The fuse holder includes internal electrical connections (not shown) that place a fuse (not shown) that is mounted within the fuse holder in series with the second power lead 149. The second power lead terminates in the receptacle connector 143. The fuse holder 145 and the connector 147 may be installed into the receptacle plate 141 prior to being installed in the power top module 100. The receptacle plate 141 can then be mounted with screws or other fasteners to integrally molded mounting bosses 159 that align with the mounting ears 157.

FIG. 7 is a rear view of the chest 10 with the rear wall removed to show the wiring harness 173 running down the back portion of the chest. A series of rear harness leads 185 extend out of the harness in alignment with each drawer's position in the chest. Each of these leads may be connected to a drawer to provide power to every drawer in the chest, or optionally, a subset of the harness leads may be connected to provide power to a selected group of drawers. The harness 173 may also be used to provide power to cavities within the chest that do not house drawers and are accessible by doors.

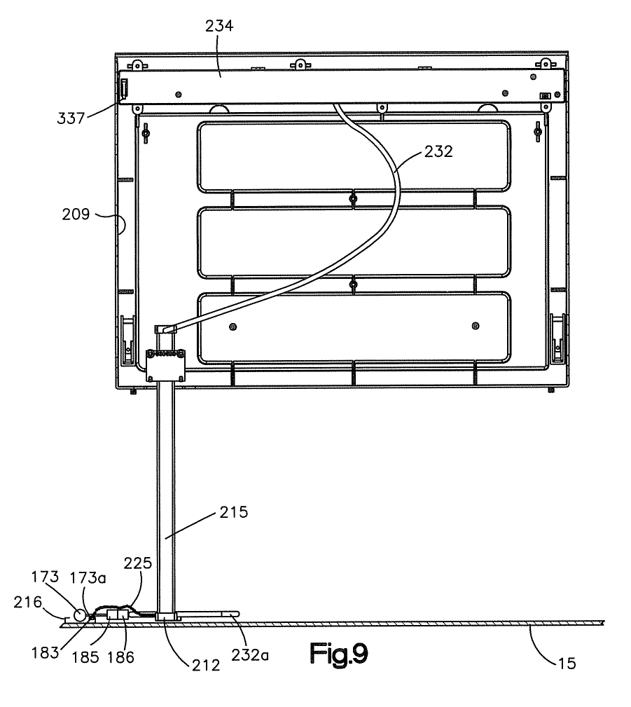

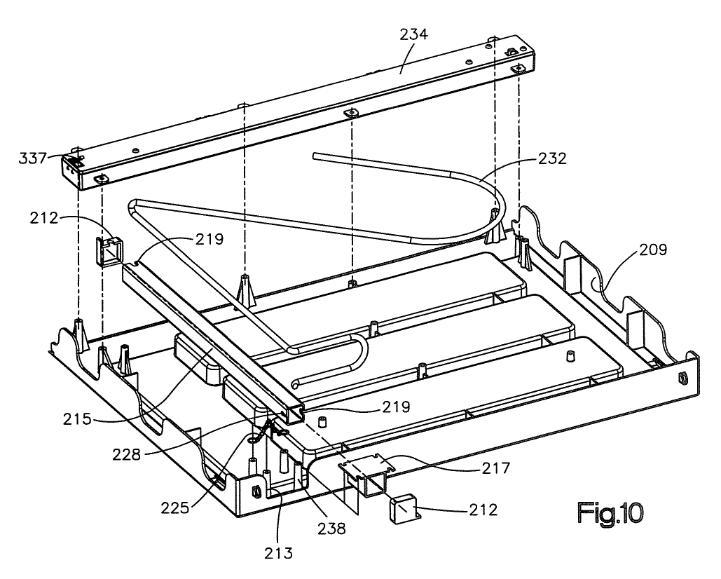

FIGS. 8-10 are bottom views of a drawer 20 that receives power from the harness 173. FIG. 8 depicts a drawer in the closed position and FIG. 9 depicts the drawer in the open position. A cable management module 209 that is installed in each powered drawer is shown in the exploded view in FIG. 10. The cable management module 209 is a molded plastic tray configured to connect to a bottom of a drawer to be powered. The cable management module 209 has a relatively shallow depth and includes a plurality of bosses 238 that mount cable management components to the bottom of the drawer. A drawer wire 232 is located in the cable management module 209. The drawer wire 232 is shown connected to a light module 234 that illuminates the space below the drawer. However, the drawer wire could also be routed to an in-drawer power jack, one example of which is indicated generally with reference numeral 265 in FIG. 7.

Referring now to FIG. 8, a harness routing channel 216 is shown running up the rear wall 15 of the chest. The channel serves to locate the harness 173 on the rear wall of the chest. A drawer pigtail 232a terminates in a drawer connector 186 that is configured to mate with the harness pigtail 185. A telescoping rod 215 is housed within a rod bracket 217 that is closely fit around the telescoping rod while allowing the rod to slide within the bracket. The drawer wire 232 passes through a first end of the telescoping rod 215 and extends through the rod to exit at a second end as the drawer pigtail 232a. The rod bracket 217 is connected to the drawer with fasteners in the bosses 238. The telescoping rod is fixed to the back of the chest with a chain 225 (best seen in FIGS. 9 and 10) that allows the rod to be pulled away from the back of the chest by a distance equal to the length of the chain. The additional rod travel allowed by the chain permits the drawer to be pulled out a distance that is greater than its own depth without being limited by the length of the telescoping rod 215. The chain 225 is connected between a keyhole notch 228 punched in a distal end of the telescoping rod 215 and a keyhole notch 183 that is cut in one flange that forms the channel 216. A grommet 212 is pressed into either end of the telescoping rod. A rod clearance notch 213 is provided in the back of the cable management module 209 to permit the telescoping rod to extend out the back of the drawer when the drawer is opened.

FIGS. 8 and 9 show relative positions of the cable management components as the drawer is moved from the closed position (FIG. 8) to the open position (FIG. 9). In FIG. 8, a majority of the telescoping rod 215 is located within the cable management module. In FIG. 9, as the drawer is opened, the telescoping rod 215 remains in a relatively fixed position with respect to the rear wall 15 of the chest by virtue of the chain 225 being connected to the keyhole 183. The telescoping rod 215 is pulled through the rod bracket 217 until the rod reaches an end of travel and then the telescoping rod is pulled away from the rear wall 15 until the drawer reaches its end of travel position as determined by the mechanical interaction between the drawer and the slides within which it rides. A sufficient length of chain, such as, for example, three inches, is selected so that the chain will not usually be pulled taut when the drawer reaches the end of its travel. When the drawer is opened, the wire 232 moves within the cable management module 209, but the wire is of sufficient length that it is not pulled taut. The electrical path to the drawer is thus maintained regardless of the drawer's position.

FIG. 10 illustrates the individual wire management components in more detail. Wire clearance notches 219 can be seen at either end of the telescoping rod 215. The wire notches provide an opening through which the drawer wire 232 is routed and then contained by a frictional engagement with the grommet 212 when the grommet is pressed into the telescoping rod. The chain 225 is of a commonly known type that includes a string of small metal balls connected together with a space in between. The chain can thus be installed in the keyhole 228 in the telescoping rod and the keyhole 183 in the channel 216. This arrangement permits the rod to be fixed to the rear wall 15 while providing additional clearance for increased drawer travel.

FIG. 11 illustrates a bottom view of the chest of FIG. 1. An under chest light 212 powered by the power top module is illustrated. This light illuminates the floor to aid in locating items that may have fallen as well as providing a pleasing aesthetic affect.

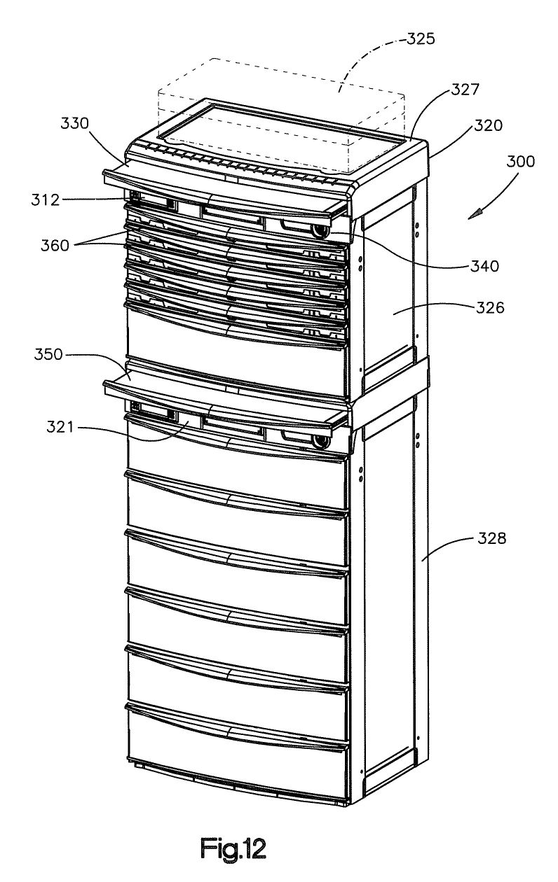

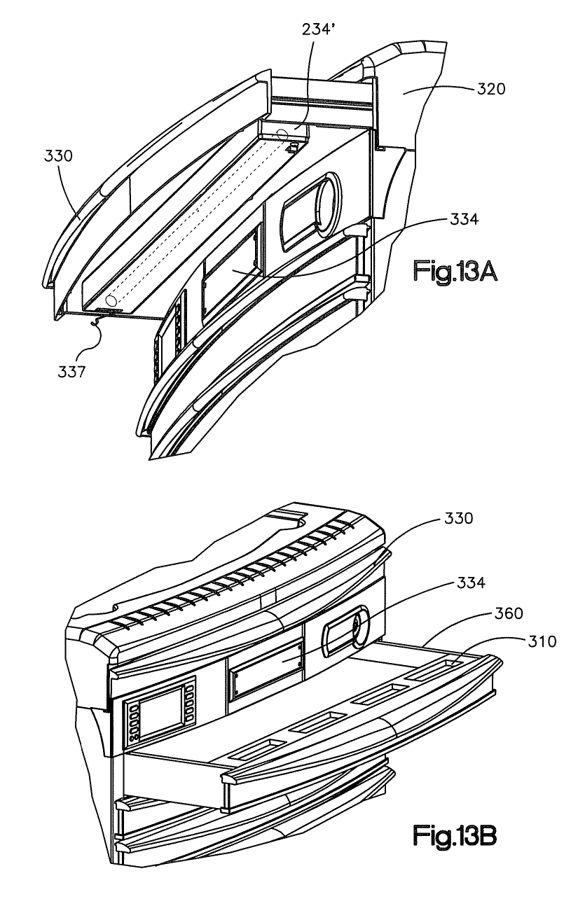

FIGS. 12 and 13A-13B illustrate a storage unit 300 that includes a chest 326 and cabinet 328. The chest 326 includes a plurality of drawers 360 and a power module 320. The cabinet includes a power module 321. Both power modules 320, 321 have similar internal power components and connections to those shown in FIGS. 4 and 6 and internal wiring harnesses to provide power to individual drawers 360 similar to those shown in FIG. 7 used to power individual drawers 20. As such, the following description will be focused on unique aspects of the power modules 320, 321 with respect to the power module 100 in FIGS. 1-11. The chest power module 320 includes a locking cylinder 340, a display 312 and lighted nameplate 334 (FIG. 13A). A top tray portion 327 of the power module 320 includes power connectors (not shown) that facilitate installation of one or more convenience accessory modules 325 that are configured to mount and connect within the top tray portion. The convenience accessory modules may be, for example, a deployable arm including a lighting module, a television, a CD player, a DVD player, a message center, an ultrasonic cleaner, a wireless communication device, a battery charger, a refrigerator, an air compressor, or a DC power jack having an industry standard configuration. Alternatively, the top tray portion 327 may not feature electrical components, but rather may serve as an additional work/storage area. A lighted drawer 330 is included in the power module 320 and a lighted pull-out work surface 350 is included in the power module 321. The lighted drawer 330 can be seen pulled away from the chest in FIG. 13A.

FIG. 13A illustrates the lighted drawer 330 pulled out of the chest 326. A light module 234′ is mounted in the underside of the drawer 330 and can be used to illuminate the space below the drawer. The light module 234′ has the same electrical connections and cable management components that are shown and discussed in conjunction with FIGS. 8-10. The light module 234′ includes a normally closed activation switch 337 that is urged open when the drawer is positioned in the chest 326 to disconnect power to the light module 234′ and returns to its closed position to provide power to the light module when the drawer is pulled out of the chest. Other switching techniques such as, for example, a magnetic reed switch, a manual switch, or a motion detecting switch can be used to activate the light. FIG. 13B illustrates a drawer 360 pulled away from the chest to expose storage cups 310 molded into a front portion of the drawer. The pull-out work surface 350 (FIG. 12) includes a light module in its underside configured similar to the light module 234′ in the lighted drawer 330.

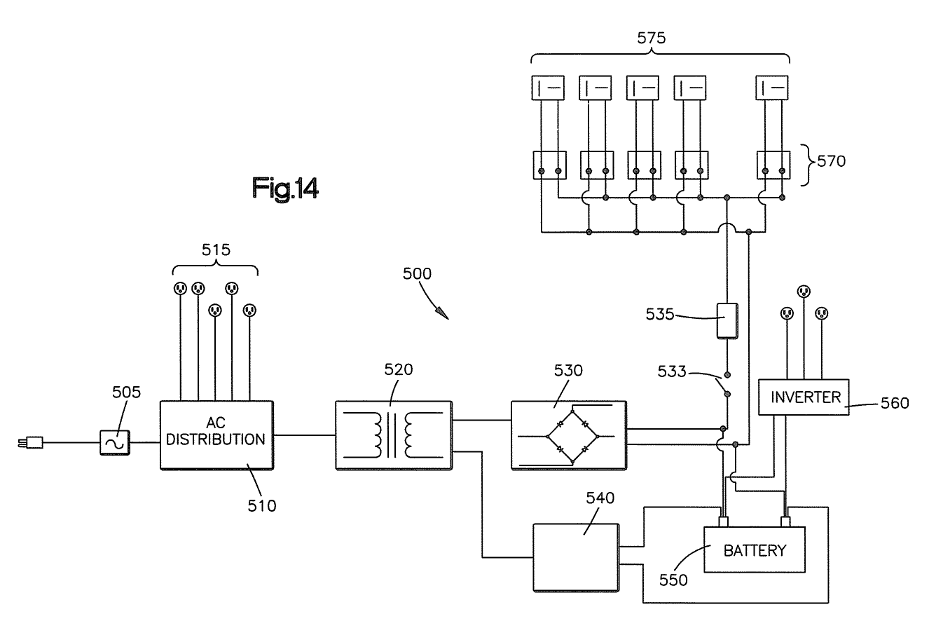

FIG. 14 is a schematic circuit diagram of a power circuit 500 that can be used to provide power to the features described above including the power top modules 100, 320, 321. The circuit 500 draws its power via a common wall plug. An over-current protection device 505 such as, for example, a fuse, thyristor, circuit breaker, or other similar device is provided to disconnect power to the circuit 500 in the event of a short circuit condition or abnormally high current draw by the circuit. An AC distribution module 510 with AC receptacles such as, for example, a terminal strip, pre-manufactured power strip or other enclosed and protected power distribution arrangement is provided to allow an AC device to be powered from the circuit 500 from either outside or inside the storage unit 300 (FIG. 12). A voltage reducing transformer 520, or other voltage reducing device, steps the supplied AC voltage down in preparation for conditioning that voltage to DC voltage. A rectifier circuit 530, such as, for example, a full wave bridge rectifier, transforms the AC voltage to DC voltage. The rectified voltage is routed through an optional DC disconnect switch 533 and to an over current protection device 535, such as, for example, a fuse or circuit breaker, that is also optional. A DC distribution circuit 570 such as, for example, a terminal strip or bus routes the DC voltage to a plurality of DC power consumer circuits 575. The DC power consumer circuits include, for example, the wiring harnesses, accessories, and lights described above and also DC power jacks that provide a convenient DC power source to the consumer.

A battery 550 is an optional electrical component in the circuit 500. The battery 550 is charged by a battery charger 540 when the wall plug is connected to power. When the wall plug is not connected to power, the battery 550 can be used to provide power the DC distribution circuit 570 as well as AC power through an inverter 560 with AC convenience receptacles.

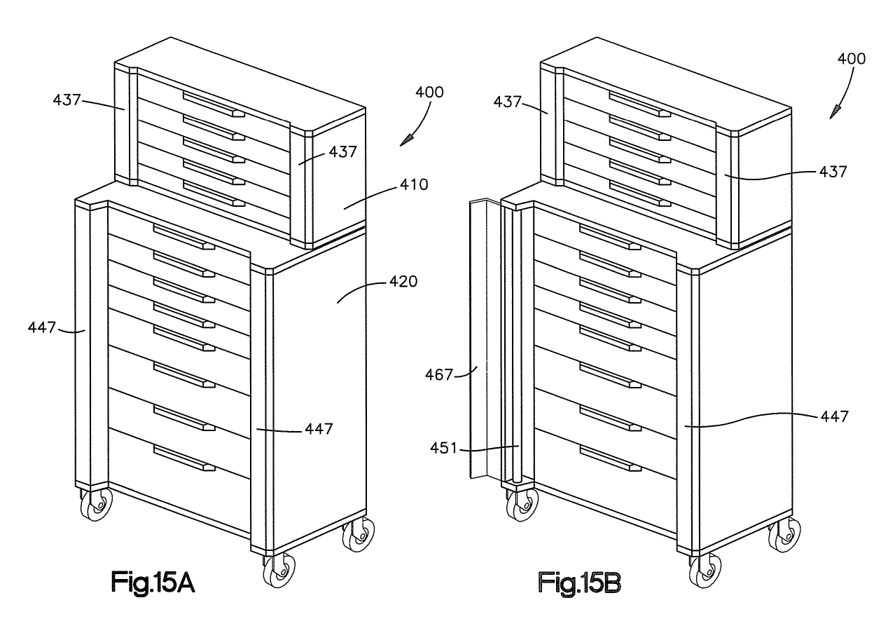

FIGS. 15A and 15B illustrate a tool storage unit 400 that includes two weldments stacked on top of one another: a chest 410 and cabinet 420. The chest 410 includes external vertically oriented light modules 437 positioned on either side of drawers in the chest. The cabinet includes external vertically oriented light modules 447. Of course, either the chest or cabinet, or both, as shown, may include the vertically oriented external light modules 437, 447. Further, the light modules may be positioned on only one side of the chest or cabinet. The external vertically oriented light module includes a protective cover 467 that may have light manipulating features such as a diffuser or decorative pattern molded into the cover. The cover 467 may be connected to the chest or cabinet with hinges as shown or may be adapted to be snap-fit to the chest or cabinet. The cover 467 protects a light bulb 451, which may be, for example, a fluorescent, neon, or incandescent bulb. The light modules 437, 447 are powered by a manual switch (not shown) and may also be powered by a motion detecting switch or other activation device.

While various aspects of the invention are described and illustrated herein as embodied in combination in the exemplary embodiments, these various aspects may be realized in many alternative embodiments not shown, either individually or in various combinations and sub-combinations thereof. Unless expressly excluded herein all such combinations and sub-combinations are intended to be within the scope of the present invention. Still further, while various alternative embodiments as to the various aspects and features of the invention, such as alternative materials, structures, configurations, methods, devices, and so on may be described herein, such descriptions are not intended to be a complete or exhaustive list of available alternative embodiments, whether presently known or later developed. Those skilled in the art may readily adapt one or more of the aspects, concepts or features of the invention into additional embodiments within the scope of the present invention even if such embodiments are not expressly disclosed herein. Additionally, even though some features, concepts or aspects of the invention may be described herein as being a preferred arrangement or method, such description is not intended to suggest that such feature is required or necessary unless expressly so stated. Still further, exemplary or representative values and ranges may be included to assist in understanding the present invention however; such values and ranges are not to be construed in a limiting sense and are intended to be critical values or ranges only if so expressly stated.

We claim:

1. A power module for a storage unit comprising:
a housing configured to attach to the storage unit;
a power receptacle mounted in the housing that receives electrical power from a source; and
a power receiving unit contained within the housing, the power receiving unit in electrical communication with the power receptacle.

2. The power module of claim 1 wherein the power receiving unit comprises a power routing harness that routes electrical power throughout the housing and the storage unit.

3. The power module of claim 1 wherein the power receiving unit comprises a convenience receptacle.

4. The power module of claim 1 wherein the housing comprises a top tray portion and wherein the power receiving unit comprises a powered storage unit accessory mounted in the top tray portion.

5. The power module of claim 1 wherein the power receiving unit comprises an audio visual device.

6. The power module of claim 1 wherein the power receiving unit comprises an ultrasonic cleaner.

7. The power module of claim 1 wherein the power receiving unit comprises a wireless communication device.

8. The power module of claim 1 wherein the power receiving unit comprises a battery charger.

9. The power module of claim 1 wherein the power receiving unit comprises a refrigerator.

10. The power module of claim 1 wherein the power receiving unit comprises an air compressor.

11. The power module of claim 1 wherein the power receiving device comprises a message center that includes a display.

12. The power module of claim 1 wherein the housing includes a slidable member installed within the housing, the slidable member configured to be partially removed from the housing to expose an underside and wherein the power receiving unit comprises one or more lights fixed on the substantially planar underside, the lights being exposed to a storage unit exterior when the slidable member is partially removed from the storage unit.

13. The power module of claim 12 wherein the slidable member comprises a drawer.

14. The power module of claim 12 wherein the slidable member comprises a slide-out work surface.

15. The power module of claim 12 comprising a light switch disposed in an electrical path between the one or more lights and the power receptacle, the light switch configured to be actuated by movement of the slidable member when the slidable member is moved away from the storage unit.

16. The power module of claim 15 wherein the light switch comprises a normally closed switch configured to be held open by a coupling between the slidable member and the switch when the slidable member is disposed within the housing.

17. The power module of claim 16 wherein the light switch is mechanically coupled to the slidable member.

18. The power module of claim 16 wherein the light switch is magnetically coupled to the slidable member.

19. The power module of claim 1 wherein the power receiving unit comprises a power storage device that is disposed in an electrical path between the power receptacle and at least one other power receiving unit.

20. The power module of claim 12 wherein the slidable member includes an electrical cable that supplies power from the power receptacle to the one or more lights, and wherein the slidable member comprises a cable management apparatus that positions the electrical cable when the slidable member is moved between being partially removed from the storage unit and being disposed within the storage unit.

21. The power module of claim 20 wherein the cable management apparatus comprises:
a cable management plenum that includes a cavity in which the electrical cable can be housed;
a telescoping rod moveably housed within the plenum and fixed to the storage unit, the telescoping rod being coupled along its length to a portion of the cable to maintain the portion of cable in fixed position relative to the telescoping rod; and
a rod guide movably coupled to the slidable member that engages the telescoping rod and maintains an alignment between the telescoping rod and the slidable member.

22. The power module of claim 21 wherein the telescoping rod comprises a hollow core in which the portion of cable is contained.

23. The power module of claim 21 wherein the telescoping end is fixed at a first distal end to the storage unit by a length of flexible chain.

24. A tool storage unit comprising:
a weldment defining a storage cavity;
a slidable member slideably maintained within the storage cavity, the slidable member moveable between a closed position in which the slidable member is substantially contained within the storage cavity and an open position in which the slidable member is partially removed from the storage cavity; and
a light mounted on an exterior surface of the weldment.

25. The tool storage unit of claim 24 wherein the light is mounted to an underside of the tool storage unit to light a space defined by a bottom surface of the tool storage unit and a surface upon which the tool storage unit rests.

26. The tool storage unit of claim 24 wherein the light is mounted in proximity to an opening in the weldment though which the slidable member slides into and out of the storage cavity.

27. The tool storage unit of claim 24 wherein the weldment comprises a light housing in which the light is mounted, the light housing including a light cover that can be moved between a closed position in which the cover is interposed between the light and an exterior space and an open position in which the light is exposed to the exterior space.

28. A storage unit comprising:
a weldment defining a storage cavity;
a slidable member slideably maintained within the storage cavity, the slidable member moveable between a closed position in which the slidable member is substantially contained within the storage cavity and an open position in which the slidable member is partially removed from the storage cavity; and
a power module connected to the weldment comprising:
a housing configured to attach to the weldment;
a power receptacle mounted in the housing that receives electrical power from a source; and
a power receiving unit contained within the housing, the power receiving unit in electrical communication with the power receptacle.

29. The storage unit of claim 28 wherein the slidable member is a drawer.

30. The storage unit of claim 28 wherein the slidable member is a slide out work surface.

31. The storage unit of claim 28 wherein the power receiving unit comprises a wiring harness that routes power to the slidable member.

32. The storage unit of claim 31 wherein the slidable member includes a convenience receptacle that provides access to power from the power module through the wiring harness.

33. The storage unit of claim 31 wherein the slidable member includes one or more lights fixed to an underside of the slidable member, the lights being exposed to a storage unit exterior when the slidable member is in the open position.

34. The storage unit of claim 33 comprising a light switch disposed in an electrical path between the one or more lights and the power receptacle, the light switch configured to be actuated by movement of the slidable member to the open position.

35. The storage unit of claim 34 wherein the light switch comprises a normally closed switch configured to be held open by a coupling between the slidable member and the switch when the slidable member is in the closed position

36. The storage unit of claim 35 wherein the light switch is mechanically coupled to the slidable member.

37. The storage unit of claim 35 wherein the light switch is magnetically coupled to the slidable member.

38. The storage unit of claim 33 wherein the slidable member includes an electrical cable that supplies power from the power receptacle to the one or more lights, and wherein the slidable member comprises a cable management apparatus that positions the electrical cable when the slidable member is moved between the open and closed position.

39. The storage unit of claim 38 wherein the cable management apparatus comprises:
a cable management plenum that includes a cavity in which the electrical cable can be housed;
a telescoping rod moveably housed within the plenum and fixed to the storage unit, the telescoping rod being coupled along its length to a portion of the cable to maintain the portion of cable in fixed position relative to the telescoping rod; and
a rod guide movably coupled to the slidable member that engages the telescoping rod and maintains an alignment between the telescoping rod and the slidable member.

40. The storage unit of claim 39 wherein the telescoping rod comprises a hollow core in which the portion of cable is contained.

41. The storage unit of claim 39 wherein the telescoping end is fixed at a first distal end to the storage unit by a length of flexible chain.

42. A tool storage unit comprising:
a weldment defining a storage cavity;
a slidable member slideably maintained within the storage cavity, the slidable member moveable between a closed position in which the slidable member is substantially contained within the storage cavity and an open position in which the slidable member is partially removed from the storage cavity; and
a light mounted to an underside of the tool storage unit to light a space defined by a bottom surface of the tool storage unit and a surface upon which the tool storage unit rests.

43. The tool storage unit of claim 42 further comprising a power module that includes:
a housing configured to attach to the tool storage unit;
a power receptacle mounted in the housing that receives electrical power from a source; and
a power routing harness contained within the housing that routes electrical power through the weldment and to the light.
